(19) United States
(12) Patent Application Publication
(10) Pub. No.: US 2025/0361608 A1
(43) Pub. Date: Nov. 27, 2025

(54) CLEANING METHOD AND FILM-FORMING APPARATUS

(71) Applicant: Tokyo Electron Limited, Tokyo (JP)

(72) Inventors: Tatsuro FUKUZUMI, Yamanashi (JP); Tsubasa YOKOI, Yamanashi (JP); Youngjun PYO, Gyeonggi-do (KR); Keisuke SUZUKI, Yamanashi (JP)

(21) Appl. No.: 19/205,415

(22) Filed: May 12, 2025

(30) Foreign Application Priority Data
May 21, 2024 (JP) 2024-082599

(51) Int. Cl. C23C 16/44; C23C 16/02; C23C 16/14; C23C 16/34; C23C 16/455; C23C 16/52

(52) U.S. Cl. CPC C23C 16/4405; C23C 16/0236; C23C 16/14; C23C 16/34; C23C 16/45544; C23C 16/52

(57) ABSTRACT

A cleaning method is for a film-forming apparatus configured to form a molybdenum film over a plurality of substrates housed in a process chamber. The cleaning method includes (a) supplying a cleaning gas into the process chamber, thereby removing the molybdenum film deposited in an interior of the process chamber; (b) after (a), coating the interior of the process chamber with a molybdenum nitride film; and (c) after (b), coating the interior of the process chamber with the molybdenum film.

### CROSS-REFERENCE TO RELATED APPLICATIONS

This application is based upon and claims priority to Japanese Patent Application No. 2024-082599, filed on May 21, 2024, the entire contents of which are incorporated herein by reference.

### BACKGROUND

### 1. Field of the Invention

The present disclosure relates to a cleaning method and a film-forming apparatus.

### 2. Description of the Related Art

A technique of forming a molybdenum film over an insulating film is known. See, for example, Japanese Patent Application Publication No. 2022-186307.

### SUMMARY

A cleaning method according to an aspect of the present disclosure is a method for cleaning a film-forming apparatus configured to form a molybdenum film over a plurality of substrates housed in a process chamber. The cleaning method includes: (a) supplying a cleaning gas into the process chamber, thereby removing the molybdenum film deposited in an interior of the process chamber; (b) after (a), coating the interior of the process chamber with a molybdenum nitride film; and (c) after (b), coating the interior of the process chamber with the molybdenum film.

### BRIEF DESCRIPTION OF THE DRAWINGS

FIG. 1 is a vertical cross-sectional view illustrating a film-forming apparatus according to an embodiment of the present disclosure;

FIG. 2 is a horizontal cross-sectional view illustrating the film-forming apparatus according to the embodiment;

FIG. 3 is a flowchart illustrating a cleaning method according to an embodiment of the present disclosure;

FIG. 4 is a flowchart illustrating an example of first coating;

FIG. 5 is a flowchart illustrating an example of second coating;

FIG. 6 is a graph illustrating a relationship between a first number of times and a thickness of a molybdenum nitride film;

FIG. 7 is a graph illustrating a relationship between a second number of times and a thickness of a molybdenum film;

FIG. 8 is a graph illustrating measurement results of the thickness of the molybdenum film in an Example; and

FIG. 9 is a graph illustrating measurement results of the thickness of the molybdenum film in a Comparative Example.

### DETAILED DESCRIPTION OF THE DISCLOSURE

The present disclosure provides a technique that can reduce a difference in film properties between the first film formation performed after cleaning, and the second and subsequent film formation performed after the cleaning.

Hereinafter, non-limiting embodiments of the present disclosure will be described with reference to the attached drawings. In the attached drawings, the same or corresponding members or parts will be denoted with the same or corresponding reference symbols, and duplicate description thereof will be omitted.

### [Film-Forming Apparatus]

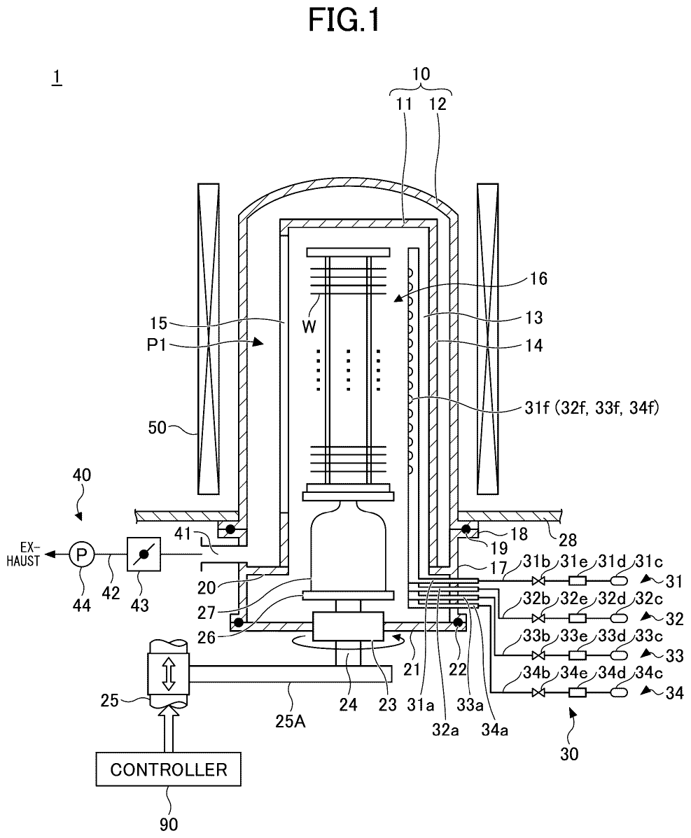

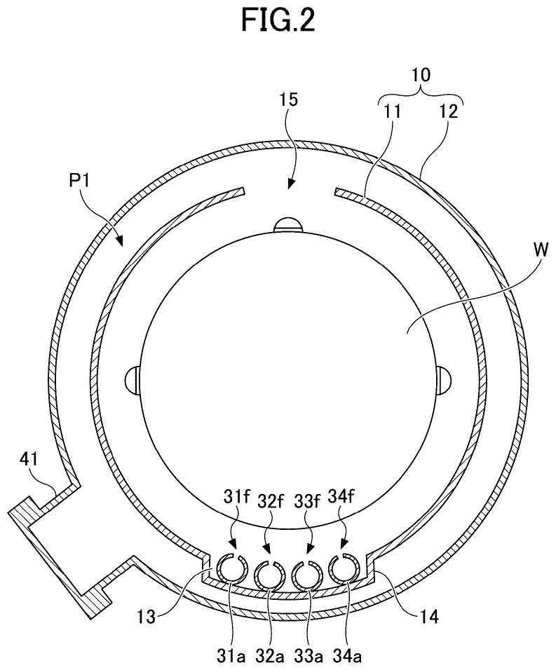

A film-forming apparatus 1 according to an embodiment of the present disclosure will be described with reference to FIGS. 1 and 2. FIG. 1 is a vertical cross-sectional view illustrating the film-forming apparatus 1 according to the embodiment. FIG. 2 is a horizontal cross-sectional view illustrating the film-forming apparatus 1 according to the embodiment.

The film-forming apparatus 1 is a batch type-apparatus configured to process a plurality of substrates W at one time. The substrates W are, for example, semiconductor wafers. The film-forming apparatus 1 includes a process chamber 10, a gas supply 30, a gas exhauster 40, a heater 50, and a controller 90.

The interior of the process chamber 10 can be reduced in pressure. The process chamber 10 is configured to house the substrates W. The process chamber 10 includes an inner tube 11 and an outer tube 12. The inner tube 11 has a cylindrical shape that has a ceiling and is open at the lower end. The outer tube 12 has a cylindrical shape that has a ceiling and is open at the lower end, and covers the exterior of the inner tube 11. The inner tube 11 and the outer tube 12 are formed of a heat-resistant material, such as quartz or the like. The inner tube 11 and the outer tube 12 form a double-tube structure in which they are disposed coaxially.

At the side wall of the inner tube 11, a housing 13 configured to house gas supply tubes along the longitudinal direction (vertical direction) is formed. For example, the side wall of the inner tube 11 is partially projected outward to form a projecting portion 14, and the interior of the projecting portion 14 is formed as the housing 13.

At the side wall of the inner tube 11, an opening 15 having a rectangular shape is formed along the longitudinal direction. The opening 15 faces the housing 13.

The opening 15 is a gas exhaust port formed to exhaust an internal gas of the inner tube 11. The opening 15 is formed such that the vertical length of the opening 15 is the same as the vertical length of a boat 16. Alternatively, the opening 15 is formed to be longer than the boat 16 in the vertical direction, i.e., extend beyond the vertical ends of the boat 16.

The lower end of the process chamber 10 is supported by a manifold 17 having a cylindrical shape. The manifold 17 is formed of stainless steel or the like. A flange 18 is formed at the upper end of the manifold 17. The flange 18 supports the lower end of the outer tube 12. A sealing 19, such as an O-ring or the like, is provided between the flange 18 and the lower end of the outer tube 12. This causes the interior of the outer tube 12 to be kept airtight.

An annular support 20 is provided at the inner wall of the top of the manifold 17. The support 20 supports the lower end of the inner tube 11. A cover 21 is airtightly attached to an opening at the lower end of the manifold 17 via a sealing 22, such as an O-ring or the like. Thus, the opening at the lower end of the process chamber 10, i.e., the opening of the manifold 17, is airtightly closed. The cover 21 is formed of stainless steel or the like.

A penetrating rotation shaft 24 is provided at the center of the cover 21 through a magnetic fluid seal 23. The bottom of the rotation shaft 24 is rotatably supported by an arm 25A of a raising and lowering mechanism 25 formed of a boat elevator.

A rotation plate 26 is provided at the upper end of the rotation shaft 24. The boat 16 configured to hold the substrates W is placed over the rotation plate 26 via a temperature-retaining stage 27 formed of quartz. The boat 16 rotates by rotation of the rotation shaft 24. The boat 16 moves upward and downward integrally with the cover 21 by raising and lowering the raising and lowering mechanism 25. Thus, the boat 16 is inserted into and removed from the process chamber 10. The boat 16 can be housed in the process chamber 10. The boat 16 holds a plurality of (e.g., 50 to 150) substrates W in the form of a shelf. The boat 16 substantially horizontally holds the plurality of substrates W at intervals in the vertical direction.

The gas supply 30 is configured to introduce various process gases into the inner tube 11. The gas supply 30 includes a MoO₂Cl₂ supply 31, an ammonia supply 32, a hydrogen supply 33, and a fluorine supply 34.

The MoO₂Cl₂ supply 31 includes a gas supply tube 31a inside the process chamber 10, and a supply flow path 31b outside the process chamber 10. The supply flow path 31b includes a MoO₂Cl₂ source 31c, a mass flow controller 31d, and a valve 31e in order from upstream to downstream in the gas flow direction. Thus, the supply timing of a MoO₂Cl₂ gas in the MoO₂Cl₂ source 31c is controlled by the valve 31e, and the flow rate of the MoO₂Cl₂ gas is adjusted to a predetermined flow rate by the mass flow controller 31d. The MoO₂Cl₂ gas flows into the gas supply tube 31a from the supply flow path 31b, and is discharged into the process chamber 10 from the gas supply tube 31a. The MoO₂Cl₂ gas is an example of a molybdenum-containing gas.

The ammonia supply 32 includes a gas supply tube 32a inside the process chamber 10, and a supply flow path 32b outside the process chamber 10. The supply flow path 32b includes an ammonia source 32c, a mass flow controller 32d, and a valve 32e in order from upstream to downstream in the gas flow direction. Thus, the supply timing of an ammonia (NH₃) gas in the ammonia source 32c is controlled by the valve 32e, and the flow rate of the ammonia gas is adjusted to a predetermined flow rate by the mass flow controller 32d. The ammonia gas flows into the gas supply tube 32a from the supply flow path 32b, and is discharged into the process chamber 10 from the gas supply tube 32a. The ammonia gas is an example of a nitriding gas.

The hydrogen supply 33 includes a gas supply tube 33a inside the process chamber 10, and a supply flow path 33b outside the process chamber 10. The supply flow path 33b includes a hydrogen source 33c, a mass flow controller 33d, and a valve 33e in order from upstream to downstream in the gas flow direction. Thus, the supply timing of a hydrogen (H₂) gas in the hydrogen source 33c is controlled by the valve 33e, and the flow rate of the hydrogen gas is adjusted to a predetermined flow rate by the mass flow controller 33d. The hydrogen gas flows into the gas supply tube 33a from the supply flow path 33b, and is discharged into the process chamber 10 from the gas supply tube 33a. The hydrogen gas is an example of a reducing gas.

The fluorine supply 34 includes a gas supply tube 34a inside the process chamber 10, and a supply flow path 34b outside the process chamber 10. The supply flow path 34b includes a fluorine source 34c, a mass flow controller 34d, and a valve 34e in order from upstream to downstream in the gas flow direction. Thus, the supply timing of a fluorine (F₂) gas in the fluorine source 34c is controlled by the valve 34e, and the flow rate of the fluorine gas is adjusted to a predetermined flow rate by the mass flow controller 34d. The fluorine gas flows into the gas supply tube 34a from the supply flow path 34b, and is discharged into the process chamber 10 from the gas supply tube 34a. The fluorine gas is an example of a cleaning gas.

The gas supply tubes 31a, 32a, 33a, and 34a are fixed to the manifold 17. The gas supply tubes 31a, 32a, 33a, and 34a are formed of quartz or the like. The gas supply tubes 31a, 32a, 33a, and 34a extend near the inner tube 11 in the form of a straight line along the vertical direction, and bend in an L shape in the manifold 17 to extend in the horizontal direction, thereby penetrating through the manifold 17. The gas supply tubes 31a, 32a, 33a, and 34a are arranged side by side along the circumferential direction of the inner tube 11, and are formed at the same height.

A plurality of discharge holes 31f, 32f, 33f, and 34f are provided at portions of the gas supply tubes 31a, 32a, 33a, and 34a that are positioned in the inner tube 11. The discharge holes 31f, 32f, 33f, and 34f are formed at predetermined intervals along the extending direction of the gas supply tubes 31a, 32a, 33a, and 34a. The discharge holes 31f, 32f, 33f, and 34f horizontally discharge the gas toward the substrate W from the outside in the radial direction of the substrate W. The discharge holes 31f, 32f, 33f, and 34f discharge gas parallel to the main surface of the substrate W. The distance between the discharge holes is set, for example, to be equal to the distance between the substrates W held by the boat 16. The position of each discharge hole in the height direction is set, for example, at the middle position between the substrates W that are next to each other in the vertical direction. In this case, each discharge hole can efficiently supply gas to a facing surface between the substrates W next to each other.

The gas supply 30 may mix two or more types of gases together, and discharge the mixed gas from a single gas supply tube. The gas supply tubes 31a, 32a, 33a, and 34a may have different shapes and arrangements. The gas supply 30 may further include a gas supply tube configured to supply another gas, e.g., an inert gas, such as an argon gas or the like.

The gas exhauster 40 is configured to exhaust the gas that is discharged through the opening 15 from the interior of the inner tube 11 and then discharged from a gas outlet 41 through a space P1 between the inner tube 11 and the outer tube 12. The gas outlet 41 is formed at the side wall upward of the manifold 17 and above the support 20. A gas exhaust path 42 is connected to the gas outlet 41. A pressure regulating valve 43 and a vacuum pump 44 are sequentially disposed in the gas exhaust path 42 with a gap such that the internal gas of the process chamber 10 can be exhausted.

The heater 50 is provided around the outer tube 12. The heater 50 is provided, for example, over a base plate 28. The heater 50 has a cylindrical shape to cover the outer tube 12. The heater 50 includes, for example, a heating element, and is configured to heat the substrates W in the process chamber 10.

The controller 90 is an electronic circuit, such as a CPU (Central Processing Unit), a FPGA (Field Programmable Gate Array), an ASIC (Application Specific Integrated Circuit), or the like. The controller 90 is configured to execute various controls described in the present specification by executing instruction codes stored in a memory or by being designed as a circuit for specific applications.

### [Cleaning Method]

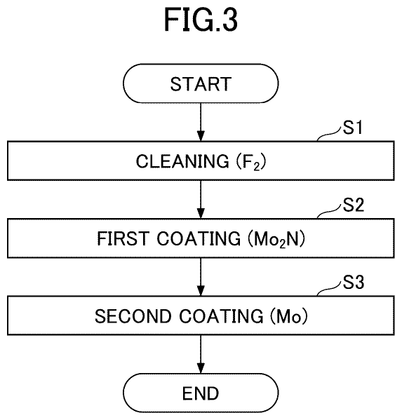

A cleaning method according to the embodiment of the present disclosure will be described with reference to FIGS. 3 to 7. In the following, the cleaning method according to the embodiment will be described taking, as an example, a cleaning method performed in the film-forming apparatus 1. The cleaning method according to the embodiment is automatically performed under the control of the controller 90. The cleaning method according to the embodiment is performed in a state in which the substrates W are absent in the process chamber 10. The cleaning method according to the embodiment is performed, for example, when a process of forming a molybdenum (Mo) film over the plurality of substrates W (hereinafter may be referred to as “film formation”) is repeatedly performed in the process chamber 10 of the film-forming apparatus 1, and the cumulative thickness of the molybdenum film deposited in the interior of the process chamber 10 exceeds a threshold thickness. When the cumulative thickness of the molybdenum film deposited in the interior of the process chamber 10 exceeds a threshold thickness, particles tend to increase.

FIG. 3 is a flowchart illustrating the cleaning method according to the embodiment. As illustrated in FIG. 3, the cleaning method according to the embodiment includes cleaning S1, first coating S2, and second coating S3.

### (Cleaning S1)

In cleaning S1, the controller 90 controls the components of the film-forming apparatus 1 so as to supply a fluorine gas into the process chamber 10 and remove the molybdenum film deposited in the interior of the process chamber 10.

First, the heater 50 adjusts the internal temperature of the process chamber 10 to a first temperature. The first temperature is 300 degrees Celsius (° C.) or more and 350 degrees Celsius (° C.) or less. Subsequently, the gas supply 30 supplies a fluorine gas into the process chamber 10, and the gas exhauster 40 maintains the interior of the process chamber 10 at a predetermined pressure. Thus, the fluorine gas reacts with the molybdenum film in the process chamber 10, thereby removing the molybdenum film deposited in the interior of the process chamber 10. When the molybdenum film deposited in the interior of the process chamber 10 is removed, the gas supply 30 stops the supply of the fluorine gas into the process chamber 10. The gas supply 30 may supply a dilution gas along with the fluorine gas. The dilution gas is an inert gas, such as a nitrogen (N₂) gas, an argon (Ar) gas, or the like.

### (First Coating S2)

First coating S2 is performed after cleaning S1. In first coating S2, the controller 90 controls the components of the film-forming apparatus 1 so as to coat the interior of the process chamber 10 with a molybdenum nitride (Mo₂N) film. The molybdenum nitride film can be formed, for example, through atomic layer deposition (ALD) in which the MoO₂Cl₂ gas and the ammonia gas are alternately supplied into the process chamber 10. Alternatively, the molybdenum nitride film can be formed through chemical vapor deposition (CVD) in which the MoO₂Cl₂ gas and the ammonia gas are supplied at the same time. The thickness of the molybdenum nitride film is, for example, 1.5 nanometers (nm) or more and 3 nanometers (nm) or less. In this case, a molybdenum film is readily formed over the molybdenum nitride film in second coating S3.

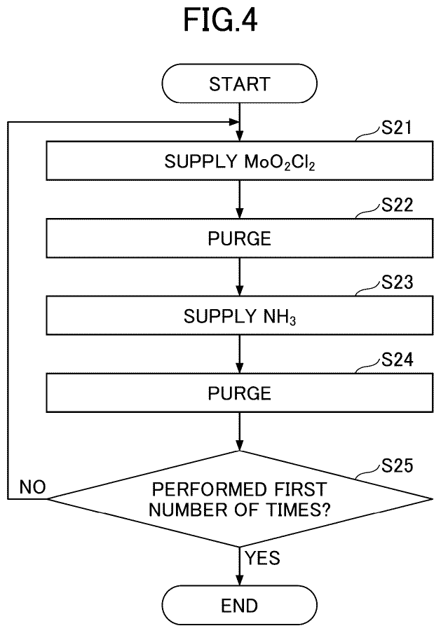

FIG. 4 is a flowchart illustrating an example of first coating S2. As illustrated in FIG. 4, first coating S2 includes steps S21 to S25. In steps S21 to S25, the heater 50 adjusts the internal temperature of the process chamber 10 to a second temperature. The second temperature is, for example, a temperature the same as the first temperature. In this case, there is no need to change the internal temperature of the process chamber 10 at the time of transition from cleaning S1 to first coating S2, resulting in an improvement in productivity. The second temperature is, for example, 250° C. or more and 600° C. or less.

In step S21, the gas supply 30 supplies the MoO₂Cl₂ gas into the process chamber 10. Thus, the MoO₂Cl₂ gas is adsorbed in the interior of the process chamber 10.

In step S22, the gas supply 30 supplies a purge gas into the process chamber 10, and the gas exhauster 40 exhausts the internal gas of the process chamber 10. This exhausts the MoO₂Cl₂ gas remaining in the process chamber 10. The supply of the purge gas and the exhaust of the gas may be performed at the same time, or may be performed at different timings. The purge gas is an inert gas, such as an argon gas, a nitrogen gas, or the like.

In step S23, the gas supply 30 supplies the ammonia gas into the process chamber 10. Thus, the MoO₂Cl₂ gas adsorbed in the interior of the process chamber 10 is nitrided, thereby forming a molybdenum nitride film.

In step S24, the gas supply 30 supplies a purge gas into the process chamber 10, and the gas exhauster 40 exhausts the internal gas of the process chamber 10. This exhausts the ammonia gas remaining in the process chamber 10. The supply of the purge gas and the exhaust of the gas may be performed at the same time, or may be performed at different timings.

In step S25, the controller 90 determines whether or not a cycle including steps S21 to S24 in this order has been performed a first number of times. If the cycle has not been performed the first number of times (NO in step S25), the controller 90 performs the cycle of steps S21 to S24 again. If the cycle has been performed the first number of times (YES in step S25), the controller 90 ends the process. Thus, by repeatedly performing the cycle of steps S21 to S24 until the cycle is performed the first number of times, the thickness of the molybdenum nitride film to be coated in the interior of the process chamber 10 is adjusted. The first number of times may be once, or may be twice or more. The first number of times is, for example, 25 times.

### (Second Coating S3)

The second coating S3 is performed after first coating S2. In second coating S3, the controller 90 controls the components of the film-forming apparatus 1 so as to coat the interior of the process chamber 10 with a molybdenum film. The molybdenum film can be formed, for example, through ALD in which the MoO₂Cl₂ gas and the hydrogen gas are alternately supplied into the process chamber 10. Alternatively, the molybdenum film can be formed through CVD in which the MoO₂Cl₂ gas and the hydrogen gas are supplied at the same time. The thickness of the molybdenum film is, for example, 100 nm or more and 120 nm or less. In this case, it is possible to reduce a variation in the thickness of the molybdenum film between the plurality of substrates W in the film formation performed after cleaning, while reducing the period of second coating S3.

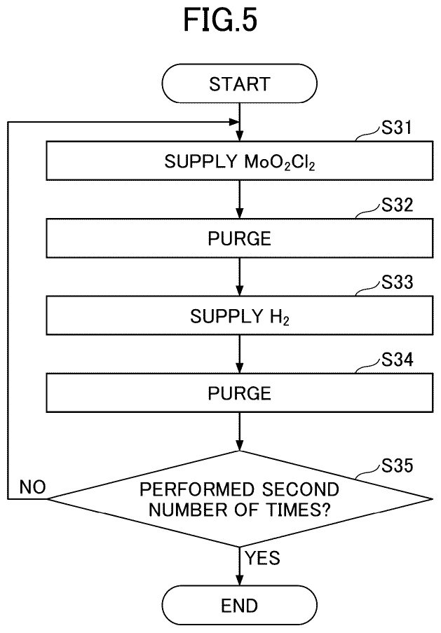

FIG. 5 is a flowchart illustrating an example of second coating S3. As illustrated in FIG. 5, second coating S3 includes steps S31 to S35. In steps S31 to S35, the heater 50 adjusts the internal temperature of the process chamber 10 to a third temperature. The third temperature is, for example, a temperature higher than the second temperature. In this case, the entirety of the interior of the process chamber 10 is readily uniformly coated with the molybdenum film. The third temperature is, for example, 450° C. or more and 600° C. or less. The third temperature may be a temperature the same as the second temperature. In this case, there is no need to change the internal temperature of the process chamber 10 at the time of transition from first coating S2 to second coating S3, resulting in an improvement in productivity.

In step S31, the gas supply 30 supplies the MoO₂Cl₂ gas into the process chamber 10. Thus, the MoO₂Cl₂ gas is adsorbed in the interior of the process chamber 10.

In step S32, the gas supply 30 supplies a purge gas into the process chamber 10, and the gas exhauster 40 exhausts the internal gas of the process chamber 10. This exhausts the MoO₂Cl₂ gas remaining in the process chamber 10. The supply of the purge gas and the exhaust of the gas may be performed at the same time, or may be performed at different timings.

In step S33, the gas supply 30 supplies a hydrogen gas into the process chamber 10. Thus, the MoO₂Cl₂ gas adsorbed in the interior of the process chamber 10 is reduced, thereby forming a molybdenum film.

In step S34, the gas supply 30 supplies a purge gas into the process chamber 10, and the gas exhauster 40 exhausts the internal gas of the process chamber 10. This exhausts the hydrogen gas remaining in the process chamber 10. The supply of the purge gas and the exhaust of the gas may be performed at the same time, or may be performed at different timings.

In step S35, the controller 90 determines whether or not a cycle including steps S31 to S34 in this order has been performed a second number of times. If the cycle has not been performed the second number of times (NO in step S35), the controller 90 performs the cycle of steps S31 to S34 again. If the cycle has been performed the second number of times (YES in step S35), the controller 90 ends the process. Thus, by repeatedly performing the cycle of steps S31 to S34 until the cycle is performed the second number of times, the thickness of the molybdenum film to be coated in the interior of the process chamber 10 is adjusted. The second number of times may be once, or may be twice or more. The second number of times is, for example, 2,000 times.

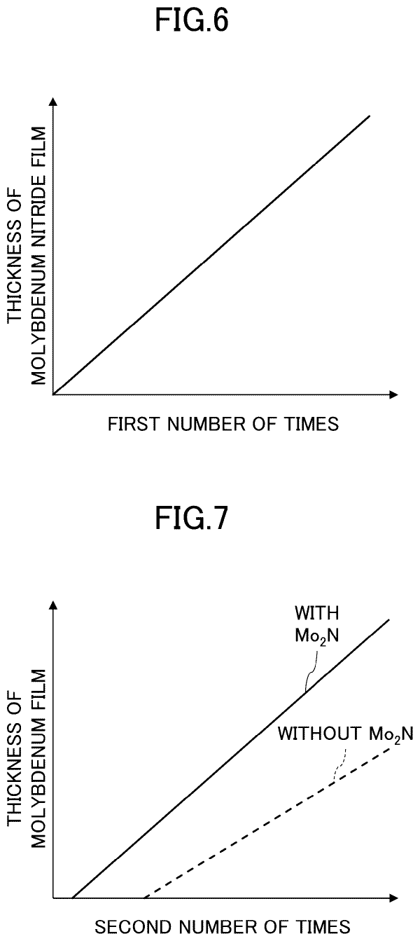

FIG. 6 is a graph illustrating a relationship between the first number of times and the thickness of the molybdenum nitride film. In FIG. 6, the horizontal axis indicates the first number of times, and the vertical axis indicates the thickness of the molybdenum nitride film formed on quartz.

As illustrated in FIG. 6, when the molybdenum nitride film is formed on quartz, the thickness of the molybdenum nitride film increases in proportion to the first number of times immediately after the start of the formation of the molybdenum nitride film. In other words, the incubation time for forming the molybdenum nitride film on quartz is very short. Therefore, the molybdenum nitride film is readily formed at portions of the process chamber 10 where the molybdenum film is not readily formed.

The portions where the molybdenum film is not readily formed include, for example, the surface of the rotation plate 26, the surface of the temperature-retaining stage 27, and the inner wall surface of the outer tube 12. The surface of the rotation plate 26 and the surface of the temperature-retaining stage 27 are outside the range of temperature control during second coating S3, and thus the temperature of these surfaces becomes low relative to the controlled temperature. Conversely, the surface of the boat 16 is controllable in terms of temperature during second coating S3. Therefore, the surface of the rotation plate 26 and the surface of the temperature-retaining stage 27 are not readily coated with the molybdenum film compared to the surface of the boat 16. The boat 16 is an example of a substrate holder, and the surface of the boat 16 is an example of a first surface. The rotation plate 26 and the temperature-retaining stage 27 are an example of a support, and the surface of the rotation plate 26 and the surface of the temperature-retaining stage 27 are an example of a second surface. The MoO₂Cl₂ gas discharged from the discharge hole 31f of the gas supply tube 31a does not readily reach the inner wall surface of the outer tube 12. Therefore, the inner wall surface of the outer tube 12 is not readily coated with the molybdenum film.

FIG. 7 is a graph illustrating a relationship between the second number of times and the thickness of the molybdenum film. In FIG. 7, the horizontal axis indicates the second number of times, and the vertical axis indicates the thickness of the molybdenum film formed on quartz. In FIG. 7, the solid line indicates the thickness of the molybdenum film in the presence of the molybdenum nitride film on quartz, and the dashed line indicates the thickness of the molybdenum film in the absence of the molybdenum nitride film on quartz.

As illustrated in FIG. 7, when the molybdenum film is to be formed on quartz in the presence of the molybdenum nitride film on the quartz, the thickness of the molybdenum film increases in proportion to the second number of times immediately after the start of the formation of the molybdenum film. With respect to the above, in the absence of the molybdenum nitride film on quartz, the thickness of the molybdenum film increases in proportion to the second number of times after the molybdenum film-forming cycle has been performed a predetermined number of times from the start of the formation of the molybdenum film. In other words, the incubation time for forming the molybdenum film on quartz is shorter in the presence of the molybdenum nitride film on the quartz than in the absence of the molybdenum nitride film on the quartz. Therefore, by forming the molybdenum film in the presence of the molybdenum nitride film on quartz, it is possible to readily form the molybdenum film at the portions of the process chamber 10 where the molybdenum film is not readily formed. That is, the entirety of the interior of the process chamber 10 can be coated with the molybdenum film. This allows the coating state of the molybdenum film in the interior of the process chamber 10 at the time of the first film formation performed after cleaning to be closer to the coating state of the molybdenum film in the interior of the process chamber 10 at the time of the second film formation performed after the cleaning. As a result, it is possible to reduce a difference in film properties between the first film formation performed after cleaning and the second and subsequent film formation performed after the cleaning.

With respect to the above, if there are portions of the process chamber 10 where the molybdenum film is not coated, the MoO₂Cl₂ gas is not readily adsorbed onto these portions in the first film formation performed after cleaning, and the amount of the MoO₂Cl₂ gas used at these portions decreases. As a result, the concentration of the MoO₂Cl₂ gas near the boat 16 increases commensurately with the amount of the MoO₂Cl₂ gas not used at these portions. This increases the thickness of the molybdenum film formed over the plurality of substrates W held by the boat 16. In the first film formation performed after cleaning, the molybdenum film begins to be coated on these portions over time. As a result, in the second film formation performed after the cleaning, the concentration of the MoO₂Cl₂ gas near the boat 16 decreases compared to the first film formation. In this manner, the internal state of the process chamber 10 at the time of the first film formation performed after cleaning differs from the internal state of the process chamber 10 at the time of the second film formation performed after the cleaning. This tends to cause a difference in the film properties between the first film formation performed after cleaning and the second film formation after the cleaning.

### EXAMPLES

In an Example, first, the film-forming apparatus 1 was caused to sequentially perform cleaning S1, first coating S2, and second coating S3 of the cleaning method according to the embodiment. Next, the film formation was performed three times in the process chamber 10. Next, the thicknesses of the molybdenum films formed over the substrates W in the first, second, and third film formation were measured.

In a Comparative Example, first, the film-forming apparatus 1 was caused to sequentially perform cleaning S1 and second coating S3 of the cleaning method according to the embodiment. In the Comparative Example, first coating S2 was not performed. Next, the film formation was performed three times in the process chamber 10 under the same conditions as in the Example. Next, the thicknesses of the molybdenum films formed over the substrates W in the first, second, and third film formation were measured.

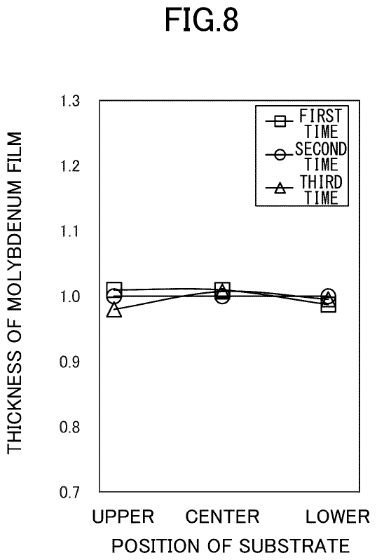

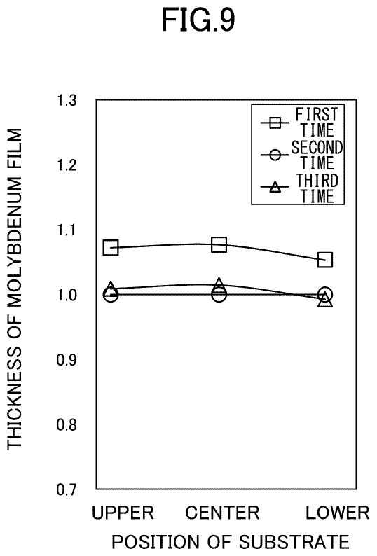

FIG. 8 is a graph illustrating measurement results of the thickness of the molybdenum film in the Example. FIG. 9 is a graph illustrating measurement results of the thickness of the molybdenum film in the Comparative Example. In FIGS. 8 and 9, the horizontal axis indicates the position of the substrate W, i.e., an upper position, a center position, or a lower position of the boat 16. In FIGS. 8 and 9, the vertical axis indicates the thicknesses of the molybdenum films formed in the first, second, and third film formation, as a relative value with the thicknesses of the molybdenum films formed in the second film formation being 1. In FIGS. 8 and 9, the squares, circles, and triangles respectively indicate the thicknesses of the molybdenum films formed in the first, second, and third film formation.

As illustrated in FIG. 8, in the Example, the thicknesses of the molybdenum films formed in the first film formation are substantially the same as the thicknesses of the molybdenum films formed in the second and third film formation. As illustrated in FIG. 9, in the Comparative Example, the thicknesses of the molybdenum films formed in the first film formation are larger than the thicknesses of the molybdenum films formed in the second and third film formation. This demonstrates that, by sequentially performing cleaning S1, first coating S2, and second coating S3, it is possible to reduce a difference in film properties between the first film formation performed after cleaning and the second and subsequent film formation performed after the cleaning.

The embodiments disclosed herein should be considered exemplary in all respects, not restrictive. Omissions, substitutions, and modifications may be made in various forms to the above embodiments without departing from the scope and intent of the claims recited.

Although the cleaning gas is a fluorine gas in the above embodiments, the present disclosure is not limited to this. For example, the cleaning gas may be a chlorine (Cl₂) gas.

Although the molybdenum-containing gas is a MoO₂Cl₂ gas in the above embodiments, the present disclosure is not limited to this. For example, the molybdenum-containing gas may be a MoCl₅ gas.

Although the nitriding gas is an ammonia gas in the above embodiments, the present disclosure is not limited to this. For example, the nitriding gas may be a N₂ gas.

According to the present disclosure, it is possible to reduce a difference in film properties between the first film formation performed after cleaning, and the second and subsequent film formation performed after the cleaning.

What is claimed is:

1. A cleaning method for a film-forming apparatus configured to form a molybdenum film over a plurality of substrates housed in a process chamber, the cleaning method comprising:
(a) supplying a cleaning gas into the process chamber, thereby removing the molybdenum film deposited in an interior of the process chamber;
(b) after (a), coating the interior of the process chamber with a molybdenum nitride film; and
(c) after (b), coating the interior of the process chamber with the molybdenum film.

2. The cleaning method according to claim 1, wherein
(a) is performed after the molybdenum film is formed over the plurality of substrates in the process chamber.

3. The cleaning method according to claim 1, wherein
(b) includes supplying a molybdenum-containing gas and a nitriding gas alternately into the process chamber.

4. The cleaning method according to claim 1, wherein
(c) includes supplying a molybdenum-containing gas and a reducing gas alternately into the process chamber.

5. The cleaning method according to claim 1, wherein
(c) is performed at a temperature that is higher than a temperature at which (b) is performed.

6. The cleaning method according to claim 1, wherein
(c) is performed at a temperature that is same as a temperature at which (b) is performed.

7. The cleaning method according to claim 1, wherein
(a), (b), and (c) are performed in a state in which no substrate is in the process chamber.

8. The cleaning method according to claim 1, wherein
the cleaning gas is a fluorine gas.

9. The cleaning method according to claim 1, wherein
a first surface and a second surface are in the process chamber, the second surface being maintained at a temperature that is lower than a temperature of the first surface, and
(b) includes coating the first surface and the second surface with the molybdenum nitride film.

10. The cleaning method according to claim 9, wherein
the first surface is a surface of a substrate holder configured to hold the plurality of substrates, and
the second surface is a surface of a support configured to support the substrate holder.

11. A film-forming apparatus configured to form a molybdenum film over a plurality of substrates housed in a process chamber, the film-forming apparatus comprising:
the process chamber;
a gas supply configured to supply a process gas into the process chamber; and
a controller including a circuit, wherein
the circuit is configured to execute
(a) supplying a cleaning gas into the process chamber, thereby removing the molybdenum film deposited in an interior of the process chamber;
(b) after (a), coating the interior of the process chamber with a molybdenum nitride film; and
(c) after (b), coating the interior of the process chamber with the molybdenum film.
